(19) United States
(12) Patent Application Publication
(10) Pub. No.: US 2026/0164747 A1
(43) Pub. Date: Jun. 11, 2026

(54) SEMICONDUCTOR STRUCTURE AND MANUFACTURING METHOD THEREOF

(71) Applicant: Champ-Asia Semiconductor Corporation, Hsinchu City (TW)

(72) Inventors: Jui-Lun Chung, Hsinchu City (TW); Tzuen-Yang Ye, Hsinchu City (TW)

(21) Appl. No.: 19/213,453

(22) Filed: May 20, 2025

(30) Foreign Application Priority Data
Dec. 11, 2024 (TW) 113148015

(51) Int. Cl. H10D 64/00; H10D 30/01; H10D 30/47; H10D 64/01

(52) U.S. Cl. CPC H10D 64/112; H10D 30/015; H10D 30/471; H10D 64/01

(57) ABSTRACT

A semiconductor structure and a manufacturing method are provided. The semiconductor structure comprises a substrate, a channel layer, an electrode, and a multilayer field plate. The channel layer is disposed above the substrate. The electrode is disposed above the channel layer. The multilayer field plate is electrically connected to the electrode and includes at least a first field plate and a second field plate. The first field plate partially overlaps and connects with the electrode. The second field plate partially overlaps and connects with the first field plate. The electrode and the multilayer field plate are configured to collectively form a continuous stepped structure. The term of partially overlapping and connecting refers to a configuration of partially direct physical contact and connection without any intervening structures.

### CROSS-REFERENCES TO RELATED APPLICATIONS

This application claims the benefit of priority to Taiwanese Patent Application No. 113148015 filed on Dec. 11, 2024, which is hereby incorporated by reference in its entirety.

### BACKGROUND OF THE INVENTION

### Field of the Invention

The present invention relates to a semiconductor structure and a manufacturing method thereof, and in particular to a power semiconductor structure and a manufacturing method thereof.

### Descriptions of the Related Art

In recent years, due to the increasing demand for high-frequency and high-power products, power semiconductor devices made of gallium nitride (GaN), such as aluminum gallium nitride/gallium nitride (AlGaN/GaN), have been widely adopted in high-power semiconductor structures, especially in radio frequency (RF) and power applications. This is attributed to their wide bandgap and high electron mobility, enabling extremely fast switching speeds and operation under high-frequency, high-power, and high-temperature conditions. Traditionally, high electron mobility transistors (HEMTs) utilize Group III-V semiconductor stacks to form a heterojunction at their interface. Due to band bending at the heterojunction, a potential well is formed within the conduction band depth, resulting in the formation of a two-dimensional electron gas (2DEG) within the potential well.

In high electron mobility transistors of gallium nitride, the channel resistance of the device is not constant under different operating conditions (e.g., bias and frequency variations) but changes with the operating state, particularly during switching operations or high-voltage conditions. An increase in dynamic resistance introduces several issues, such as increased power loss and reduced overall efficiency, especially in high-frequency operations. Furthermore, the increase in dynamic resistance raises the time constant, thereby affecting switching speed and diminishing the advantage of rapid switching in power devices, particularly in high-frequency applications.

To mitigate the issue of dynamic resistance, incorporating an additional field plate structure into the gate structure plays a crucial role. The main function of the gate field plate is to alleviate electric field concentration by distributing the electric field over a wider area, reducing electric field peaks to minimize or delay the dynamic resistance effect. Consequently, the addition of a field plate design reduces fluctuations in the device's dynamic resistance, which is particularly effective in high-voltage applications, enhancing the reliability and performance of power devices.

However, in the current manufacturing process of power devices, adding field plate structures requires multiple via etching steps and multiple metal deposition processes to complete the field plates. For example, in the mainstream 650-volt depletion-mode high electron mobility transistor (D-mode HEMT) with a three-layer field plate design, as shown in FIG. 1, fabricating three field plates without affecting the dielectric layer beneath the gate metal requires four separate metal deposition steps (gate metal GM, first field plate FP1, second field plate FP2, and third field plate FP3) and three via etching steps (V1, V2, V3), totaling seven layered structures. This results in lengthy process times and high production costs. To address these issues, the industry urgently needs an innovative semiconductor structure to optimize the field plate design and reduce production time and costs.

### SUMMARY OF THE INVENTION

The main objective of the present invention is to provide an innovative semiconductor structure by repeatedly stacking dielectric layers and barrier layers with a high etching selectivity ratio, combined with a patterned etching process, to form a multilayer field plate with a continuous stepped structure, thereby mitigating the dynamic resistance effect in power devices caused by electric field concentration.

To achieve the above objective, the present invention provides a semiconductor structure comprising a substrate, a channel layer, an electrode, and a multilayer field plate. The channel layer is disposed above the substrate, and the electrode is disposed above the channel layer. The multilayer field plate is electrically connected to the electrode and includes at least a first field plate and a second field plate, wherein the first field plate partially overlaps and connects with the electrode, and the second field plate partially overlaps and connects with the first field plate such that the electrode and the multilayer field plate jointly form a continuous stepped structure, wherein the term “partially overlapping and connecting” refers to a configuration of partial direct physical contact and connection without any intervening structure.

In an embodiment of the semiconductor structure of the present invention, the electrode is one of a gate electrode, a source electrode, or a drain electrode.

In an embodiment of the semiconductor structure of the present invention, the semiconductor structure further comprises a first barrier layer and a first dielectric layer, wherein the first dielectric layer covers the first barrier layer, and the first barrier layer and the first dielectric layer jointly define a contour of the electrode.

In an embodiment of the semiconductor structure of the present invention, the semiconductor structure further comprises a second barrier layer and a second dielectric layer, wherein the second dielectric layer covers the second barrier layer, the second barrier layer covers the first dielectric layer, and the second barrier layer and the second dielectric layer jointly define a contour of the first field plate.

In an embodiment of the semiconductor structure of the present invention, the first barrier layer and the first dielectric layer jointly define a first critical dimension, the second barrier layer and the second dielectric layer jointly define a second critical dimension, and the first critical dimension is smaller than the second critical dimension, wherein the first critical dimension and the second critical dimension are respectively the maximum lateral dimensions of the electrode and the first field plate.

In an embodiment of the semiconductor structure of the present invention, the first barrier layer and the second barrier layer are one of an aluminum nitride (AlN) layer, a gallium oxide (Ga₂O₃) layer, or an aluminum oxide (Al₂O₃) layer.

In an embodiment of the semiconductor structure of the present invention, the first dielectric layer and the second dielectric layer are one of a silicon nitride (SiN) layer, a silicon oxide (SiO₂) layer, a silicon oxynitride (SiON) layer, or a silicon carbide (SiC) layer.

In an embodiment of the semiconductor structure of the present invention, the substrate is one of a silicon substrate, a sapphire substrate, a silicon carbide substrate, a diamond substrate, or a gallium nitride substrate.

To achieve the above objective, the present invention provides a manufacturing method of a semiconductor structure, comprising: forming a channel layer disposed above a substrate; and forming an electrode and a multilayer field plate disposed above the channel layer in a single process, wherein the multilayer field plate is electrically connected to the electrode, the multilayer field plate includes at least a first field plate and a second field plate, the first field plate partially overlaps and connects with the electrode, and the second field plate partially overlaps and connects with the first field plate, such that the electrode and the multilayer field plate jointly form a continuous stepped structure, and wherein the term “partially overlapping and connecting” refers to a configuration of partial direct physical contact and connection without any intervening structure.

In an embodiment of the manufacturing method of the semiconductor structure of the present invention, the step of forming an electrode and a multilayer field plate comprises: sequentially forming a first barrier layer and a first dielectric layer, disposed above the channel layer; sequentially forming a second barrier layer and a second dielectric layer, disposed above the first dielectric layer; patterning and etching the second dielectric layer, and stopping the etching at the second barrier layer to expose a portion of the second barrier layer; removing the exposed portion of the second barrier layer to expose a portion of the first dielectric layer; patterning and etching the first dielectric layer, and stopping the etching at the first barrier layer to expose a portion of the first barrier layer; removing the exposed portion of the first barrier layer; and depositing a metal to cover a portion of the channel layer, a portion of the first dielectric layer, and a portion of the second dielectric layer, thereby forming the electrode and the multilayer field plate in a single process, wherein the first barrier layer and the first dielectric layer jointly define a contour of the electrode, and the second barrier layer and the second dielectric layer jointly define a contour of the first field plate.

In an embodiment of the manufacturing method of the semiconductor structure of the present invention, the step of patterning and etching the first dielectric layer and the step of removing the exposed portion of the first barrier layer jointly define a first critical dimension, the step of patterning and etching the second dielectric layer and the step of removing the exposed portion of the second barrier layer jointly define a second critical dimension, the first critical dimension is smaller than the second critical dimension, and the first critical dimension and the second critical dimension are respectively the maximum lateral dimensions of the electrode and the first field plate.

In an embodiment of the manufacturing method of the semiconductor structure of the present invention, the first barrier layer and the second barrier layer are one of an aluminum nitride (AlN) layer, a gallium oxide (Ga₂O₃) layer, or an aluminum oxide (Al₂O₃) layer.

In an embodiment of the manufacturing method of the semiconductor structure of the present invention, the first dielectric layer and the second dielectric layer are one of a silicon nitride (SiN) layer, a silicon oxide (SiO₂) layer, a silicon oxynitride (SiON) layer, or a silicon carbide (SiC) layer.

In an embodiment of the manufacturing method of the semiconductor structure of the present invention, the etching selectivity ratios of the first dielectric layer and the second dielectric layer relative to the first barrier layer and the second barrier layer are greater than 100.

In an embodiment of the manufacturing method of the semiconductor structure of the present invention, the substrate is one of a silicon substrate, a sapphire substrate, a silicon carbide substrate, a diamond substrate, or a gallium nitride substrate.

After referring to the drawings and the embodiments described subsequently, those skilled in the art will understand the other objectives of the present invention, as well as the technical means and embodiments of the present invention.

### BRIEF DESCRIPTION OF THE DRAWINGS

FIG. 1 is a schematic diagram of a conventional depletion-mode high electron mobility transistor with a three-layer multilayer field plate structure;

FIG. 2A to FIG. 2P are schematic diagrams of the manufacturing process of a semiconductor structure in an embodiment of the present invention; and

FIG. 3 is a schematic diagram of the process steps of a semiconductor structure in an embodiment of the present invention.

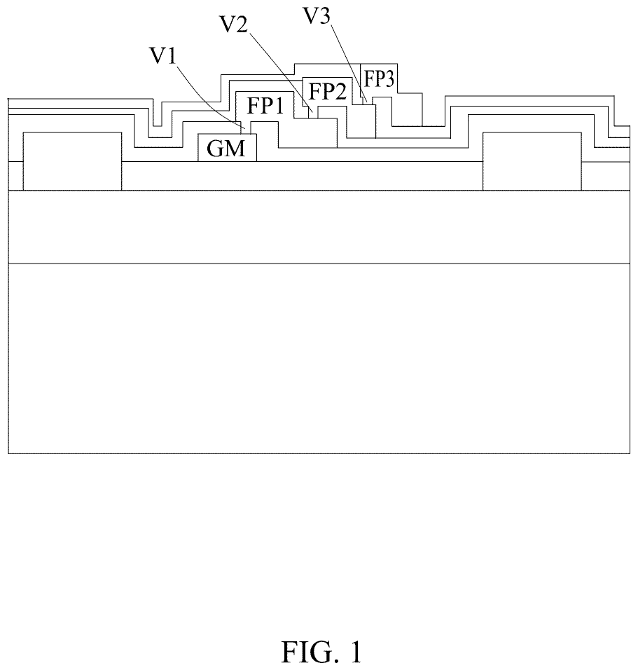

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

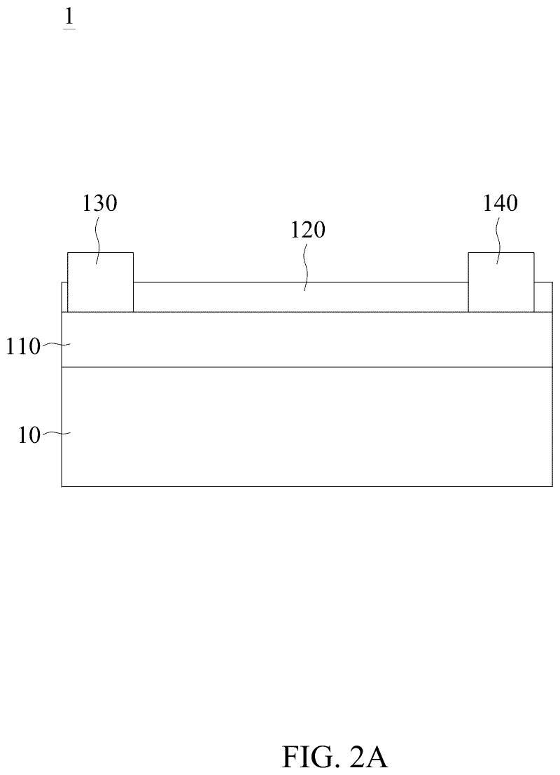

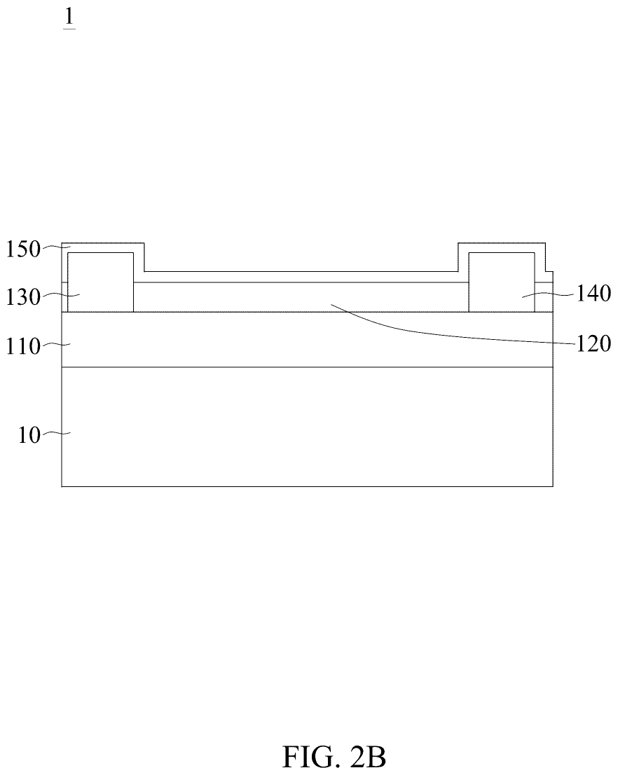

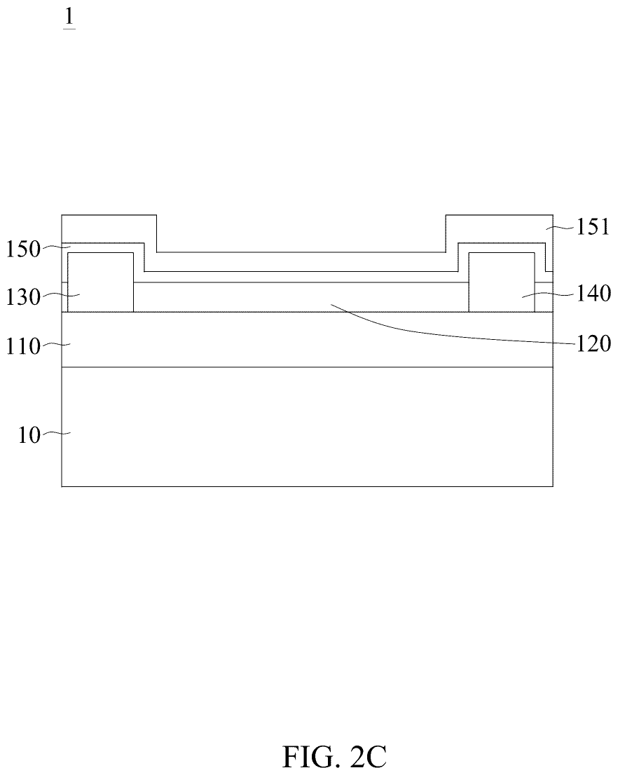

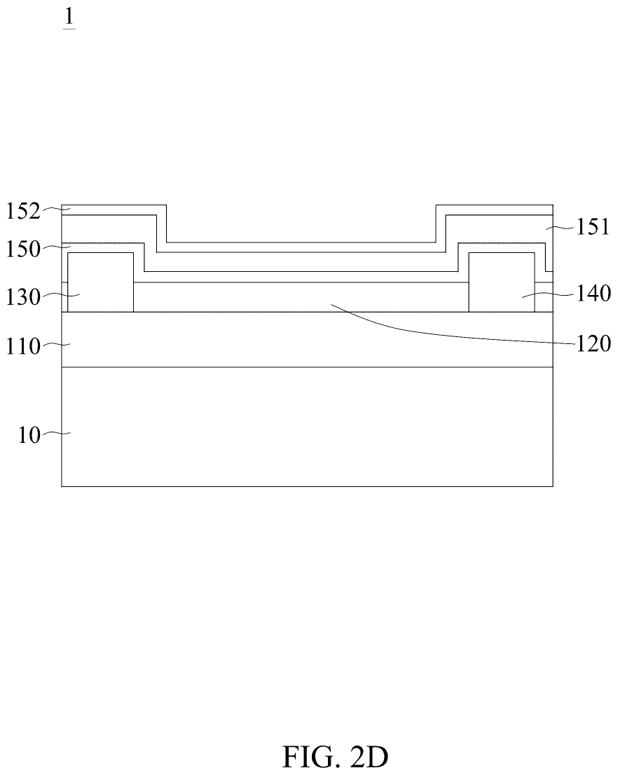

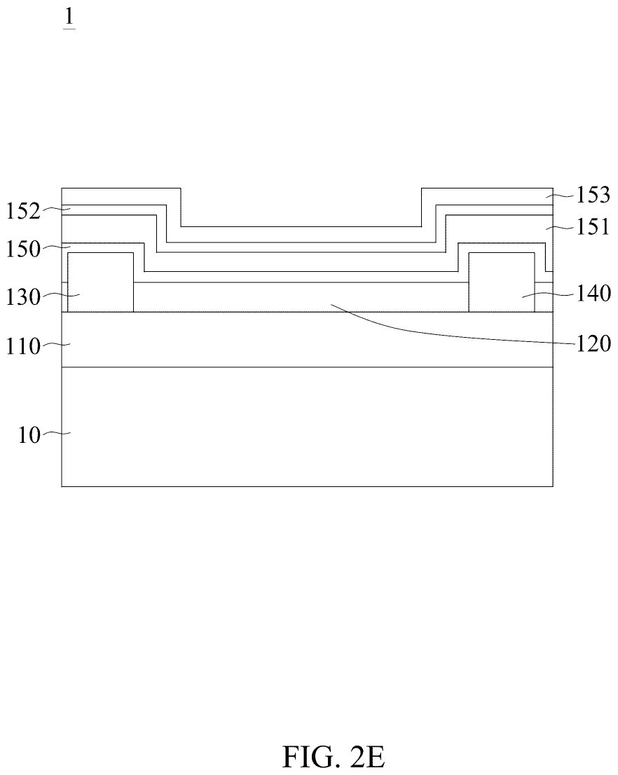

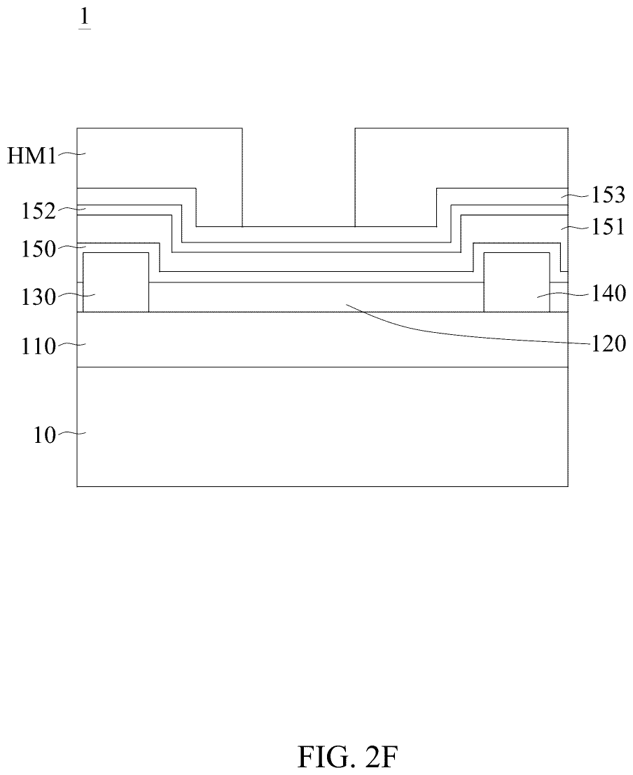

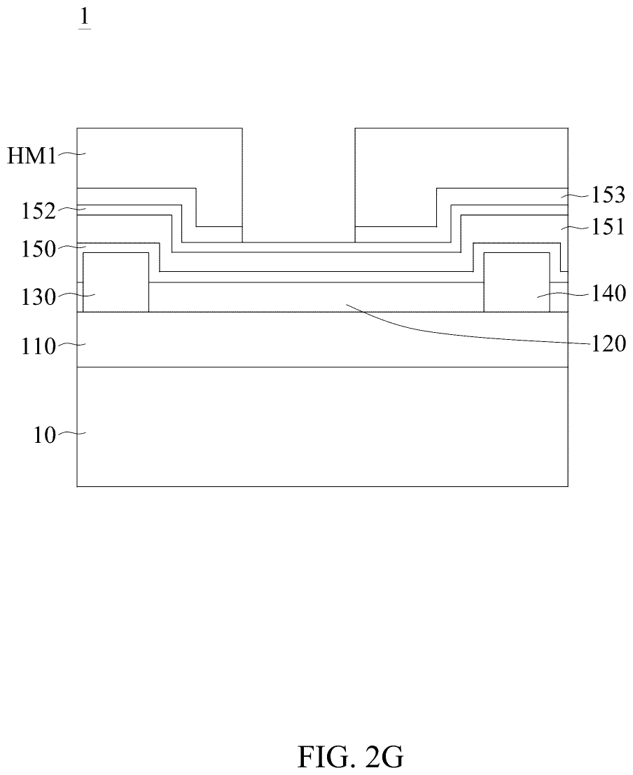

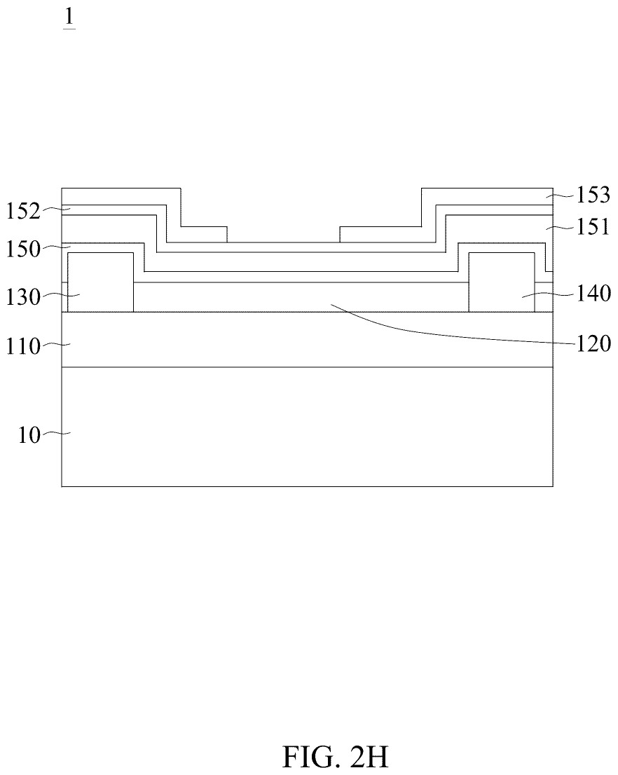

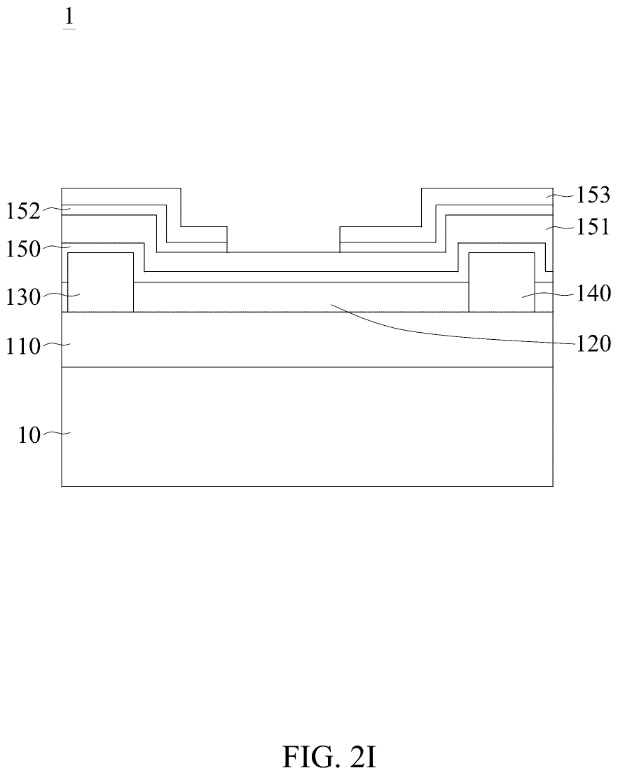

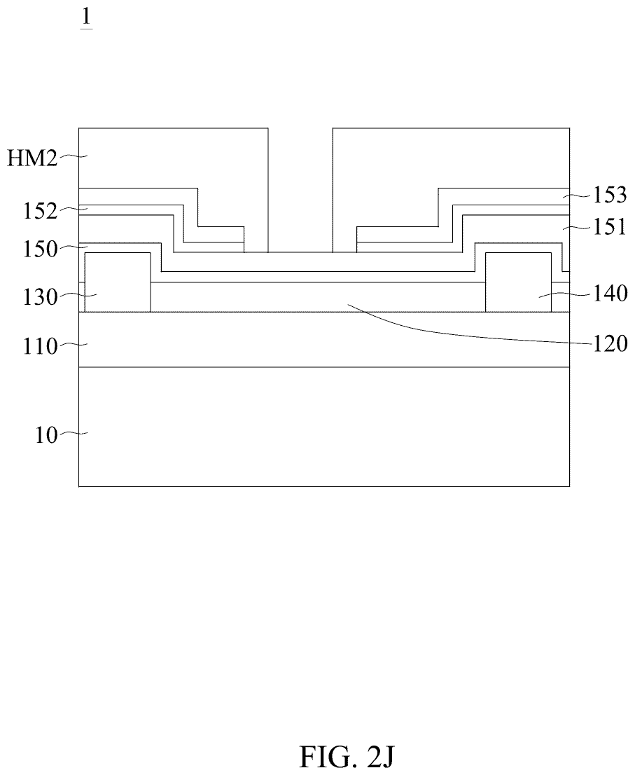

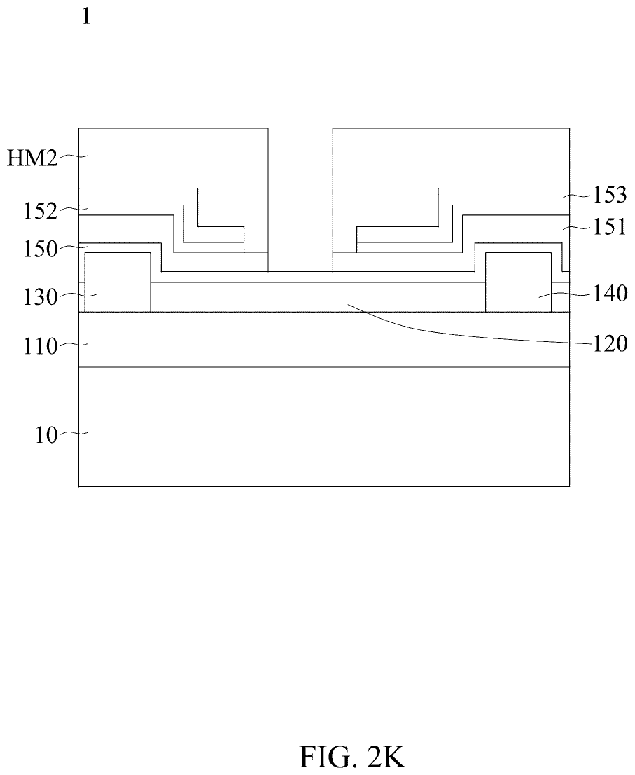

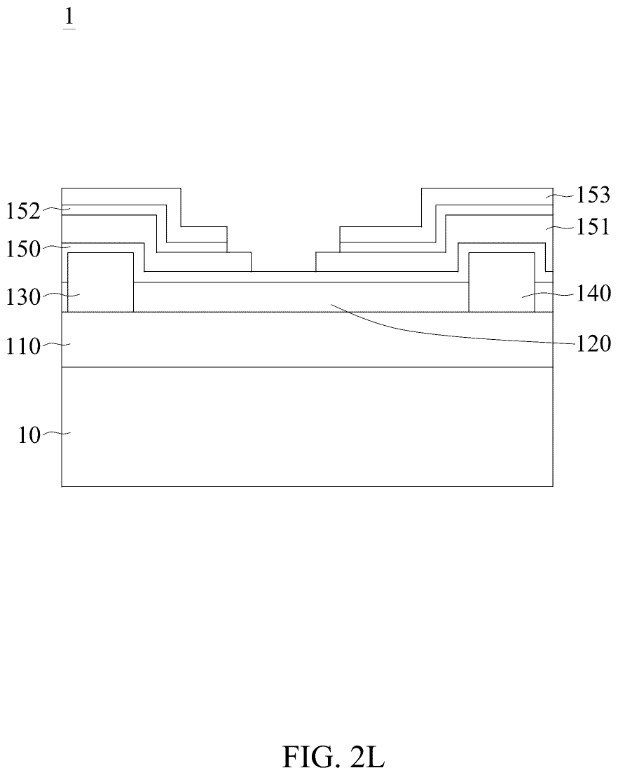

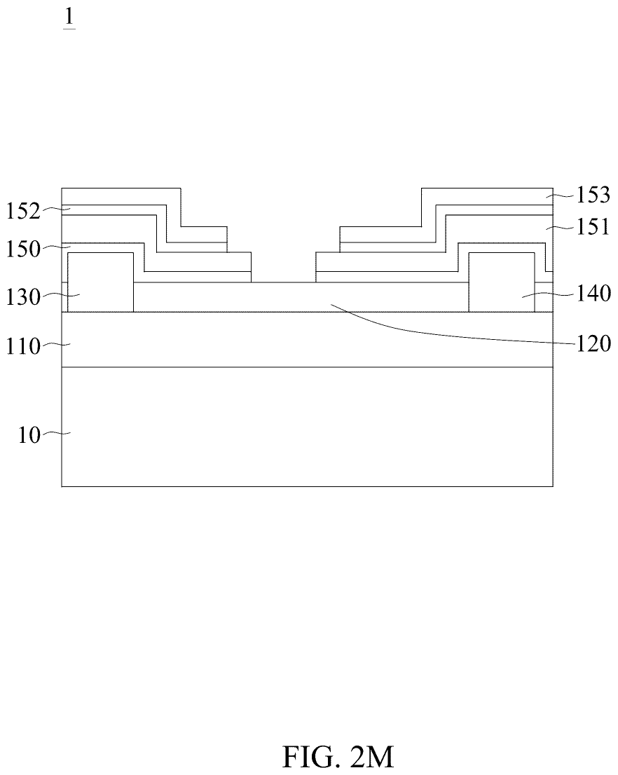

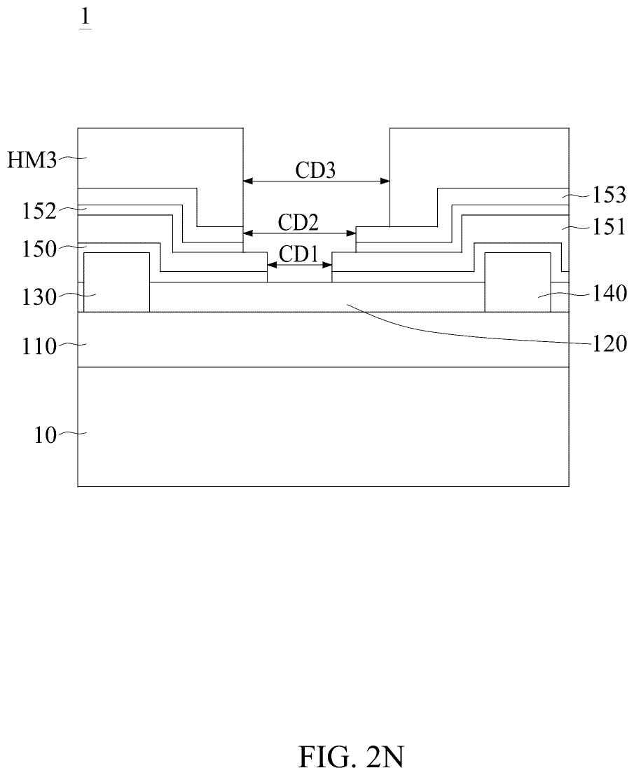

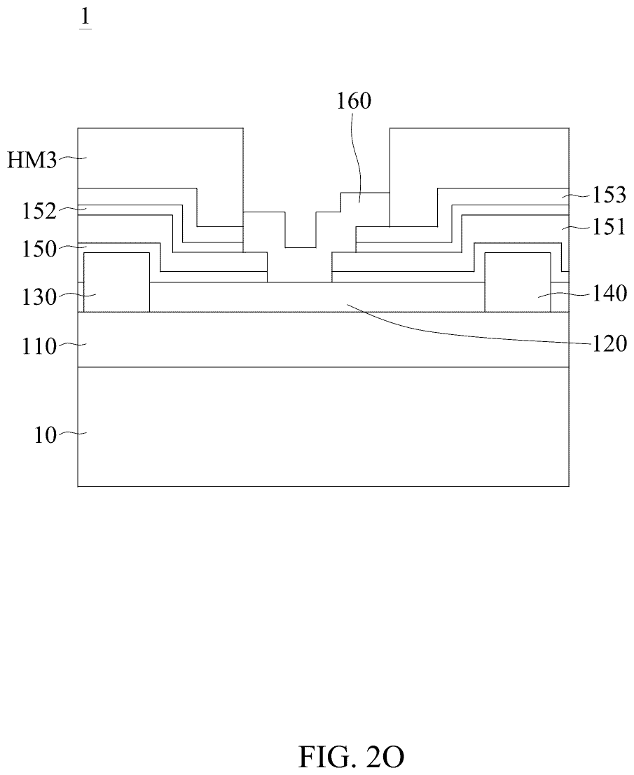

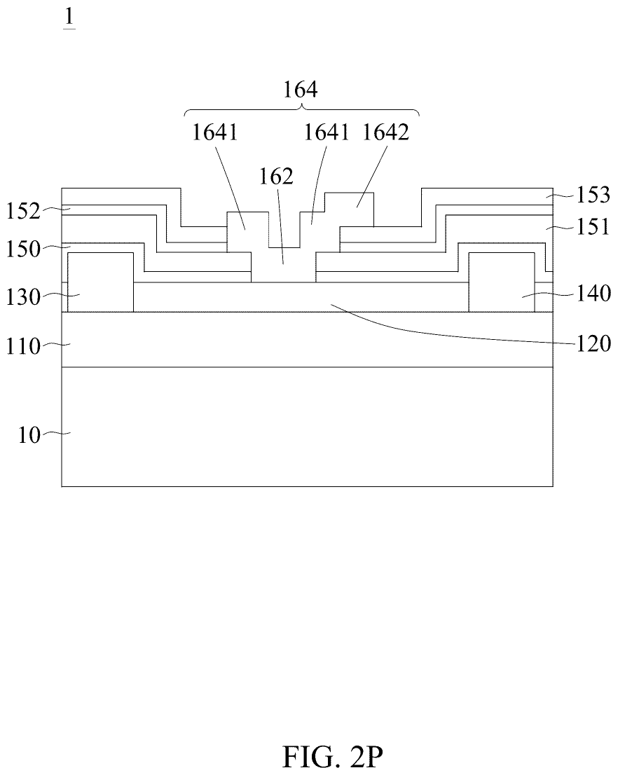

Please refer to FIG. 2A to FIG. 2P together, which illustrate the manufacturing process of a semiconductor structure 1 in an embodiment of the present invention, particularly a high electron mobility transistor and a manufacturing method thereof. As shown in FIG. 2A, a channel layer 110 and a cover layer 120 are sequentially formed on a substrate 10. The substrate 10 may be one of a silicon substrate, a sapphire substrate, a silicon carbide substrate, a diamond substrate, a gallium nitride substrate, or a gallium arsenide substrate. The channel layer 110 is formed on the substrate 10, and a cover layer 120 is formed on the channel layer 110. The channel layer 110 is further electrically connected to a source electrode 130 and a drain electrode 140. In a specific embodiment, an additional barrier layer (not shown) is present between the cover layer 120 and the channel layer 110, with the lattice constant of this barrier layer typically smaller than that of the channel layer 110. In this embodiment, the materials of the channel layer and the barrier layer include aluminum indium gallium nitride (AlₓIn_{y}Ga_{(1-x-y)}N), where 0≤x<1 and 0≤x+y≤1. In this embodiment, the channel layer 110 may be a gallium nitride layer, the barrier layer may be an aluminum gallium nitride layer or an indium gallium nitride layer, and the cover layer material includes highly doped gallium nitride (GaN), though not limited thereto, forming low-impedance ohmic contacts directly with the source and drain electrodes. Due to spontaneous polarization within the channel layer and barrier layer, as well as piezoelectric polarization between them, a two-dimensional electron gas (2DEG) is generated at the heterojunction between the channel layer and the barrier layer.

Additionally, the source electrode 130 and the drain electrode 140 can be formed on the barrier layer through a metal deposition process, using high temperatures to create alloy materials for ohmic contact. These alloy materials may be selected from the group consisting of titanium, aluminum, nickel, molybdenum, titanium nitride, gold, or combinations thereof. Specifically, the source and drain electrodes may be metal alloy systems such as titanium/aluminum/nickel/gold, titanium/aluminum/titanium/gold, titanium/aluminum/ molybdenum/gold, or titanium/aluminum/titanium/titanium nitride, though not limited thereto. On the other hand, the structural design of the aforementioned channel layer can be modified based on device requirements. For example, the semiconductor structure of the present invention can be applied to P-type doped gallium nitride enhancement-mode high electron mobility transistors (pGaN E-mode HEMT), P-type doped gallium nitride depletion-mode high electron mobility transistors (pGaN D-mode HEMT), normally-off HEMT devices with a recessed gate structure or fluorine ion doping (F Implant), and enhancement/depletion-mode integrated circuits (E/D-mode IC).

Please continue referring to FIG. 2B. Next, a deposition process for a first barrier layer 150 is performed, depositing the first barrier layer 150 above the channel layer 110 to cover the cover layer 120, the source electrode 130, and the drain electrode 140. The material of this first barrier layer may be, for example, but not limited to, aluminum nitride (AlN), gallium oxide (Ga₂O₃), or aluminum oxide (Al₂O₃). Subsequently, a first dielectric layer 151 is deposited to cover the first barrier layer 150, as shown in FIG. 2C. The material of this first dielectric layer may be, for example, but not limited to, silicon nitride (SiN), silicon oxide (SiO₂), silicon oxynitride (SiON), or silicon carbide (SiC). It should be noted that the present invention appropriately selects the constituent materials of the barrier layer and dielectric layer so that the first dielectric layer has a high etching selectivity ratio relative to the first barrier layer. Optimally, this etching selectivity ratio is greater than 100, reducing the number of mask usages in subsequent processes and further eliminating the need for via structures required for electrical connections between the electrode and field plate, as well as between adjacent field plates in the multilayer field plate, as detailed below.

Please refer to FIG. 2D and FIG. 2E together. Next, a second barrier layer 152 is deposited to cover the first dielectric layer 151, and a second dielectric layer 153 is deposited to cover the second barrier layer 152. The constituent material of the second barrier layer is the same as that of the first barrier layer. Similarly, the constituent material of the second dielectric layer is the same as that of the first dielectric layer. Therefore, the second dielectric layer also has a high etching selectivity ratio greater than 100 relative to the second barrier layer. Additionally, in this embodiment, two sets of composite layers are used as an example, including the first barrier layer, first dielectric layer, second barrier layer, and second dielectric layer, though not limited thereto. In practice, the number of composite layers composed of barrier layers and dielectric layers can vary depending on the number of layers in the multilayer field plate.

Please refer to FIG. 2F and FIG. 2G together, which illustrate a layered patterning and etching process. First, a patterned first photoresist layer HM1 is formed on the second dielectric layer 153. Using this patterned first photoresist layer HM1 as an etching mask, a portion of the second dielectric layer 153 is etched, and the high etching selectivity ratio between the dielectric layer and the barrier layer ensures that this etching stops at the second barrier layer 152, as shown in FIG. 2G.

Please refer to FIG. 2H and FIG. 2I together. After removing the first photoresist layer HM1, the patterned second dielectric layer 153 is used as an etching mask to etch and remove a portion of the second barrier layer 152, exposing a portion of the surface of the first dielectric layer 151. Then, refer to FIG. 2J and FIG. 2K together, where a second patterning and etching process is performed on the aforementioned patterned opening area. Specifically, a patterned second photoresist layer HM2 is formed on the patterned second dielectric layer 153 and the exposed portion of the first dielectric layer 151. Using this patterned second photoresist layer HM2 as an etching mask, a portion of the first dielectric layer 151 is etched, and the high etching selectivity ratio between the dielectric layer and the barrier layer ensures that the second patterning and etching stops at the first barrier layer 150, as shown in FIG. 2K.

Please refer to FIG. 2L and FIG. 2M together. After removing the second photoresist layer HM2, the patterned first dielectric layer 151 is used as an etching mask to etch and remove a portion of the first barrier layer 150, exposing a portion of the surface of the cover layer 120. Then, referring to FIG. 2N, a patterned third photoresist layer HM3 is formed on the exposed second dielectric layer 153 to define the contour range of the uppermost field plate structure. As shown in FIG. 2N, it is clear that the previous two patterning and etching processes leave a first opening with a first critical dimension CD1 in the first barrier layer 150 and the first dielectric layer 151, a second opening with a second critical dimension CD2 in the second barrier layer 152 and the second dielectric layer 153, and the third photoresist layer HM3 has a third opening with a third critical dimension CD3. The sizes of these three openings increase progressively from bottom to top, i.e., the first critical dimension CD1 of the first opening is smaller than the second critical dimension CD2 of the second opening, and the second critical dimension CD2 of the second opening is smaller than the third critical dimension CD3 of the third opening. This three-layer opening structure serves as the contour foundation for the subsequent gate and its field plate structure, as detailed below.

Next, a metal deposition process is performed to form a metal film in the aforementioned three-layer openings in a single process. As shown in FIG. 2O, the metal film formed in the three-layer openings has a continuous stepped structure 160. This continuous stepped structure 160 is characterized by each “stepped” structure “partially overlapping and connecting” with the adjacent upper and lower “steps.” The term “partially overlapping and connecting” refers to a physical configuration relationship of partial direct physical contact and connection without any intervening structures, such as vias. Specifically, this continuous stepped structure 160 includes a gate electrode 162 and a multilayer field plate 164, with the gate electrode 162 being partially physically and electrically connected to the multilayer field plate 164.

In detail, in this embodiment, the first barrier layer 150 and the first dielectric layer 151 jointly define a contour of the gate electrode 162. Additionally, the multilayer field plate 164 includes a first field plate 1641 and a second field plate 1642. The second barrier layer 152 and the second dielectric layer 153 jointly define a contour of the first field plate 1641, and the patterned third photoresist layer HM3 defines a contour of the second field plate 1642, as shown in FIG. 2P. That is, the first critical dimension CD1, the second critical dimension CD2, and the third critical dimension CD3 can also be defined as the maximum lateral dimensions of the gate electrode 162, the first field plate 1641, and the second field plate 1642, respectively, with the relationship CD1<CD2<CD3 among them.

As described above, the gate electrode 162 and the multilayer field plate 164 of the present invention are formed in a single metal deposition process. The gate electrode 162 and the first field plate 1641 are “partially overlapping and connecting,” meaning that a side portion of the gate electrode directly physically contacts and connects to the side of the adjacent upper first field plate 1641. Similarly, the first field plate 1641 and the second field plate 1642 are also “partially overlapping and connecting,” meaning that a side portion of the first field plate 1641 directly physically contacts and connects to the side of the adjacent upper second field plate 1642. Overall, the continuous stepped structure 160 resembles a staircase shape, extending continuously upward and outward layer by layer from the bottom, without incorporating bridging structures such as vias, as seen in traditional multilayer field plate structures. In particular, since the gate and multilayer field plate structure of the present invention form a continuous stepped structure without intervening bridging structures between layers, no dielectric layer is “embedded.” Therefore, power devices such as HEMTs applying the present invention can further reduce dielectric layer thickness and control potential gradients to alleviate electric field concentration and suppress dynamic resistance variations.

It should be noted that, although the continuous stepped structure 160 in the semiconductor structure 1 described above is exemplified with a gate electrode and a gate multilayer field plate structure, the continuous stepped structure and its manufacturing method disclosed in the present invention are not limited thereto. In essence, depending on the need to suppress dynamic resistance in power devices, the continuous stepped structure can be applied to other electrode structures, such as introducing the continuous stepped structure without via intervening structures into the source electrode and/or drain electrode, achieving optimized results in saving mask exposure time and corresponding costs.

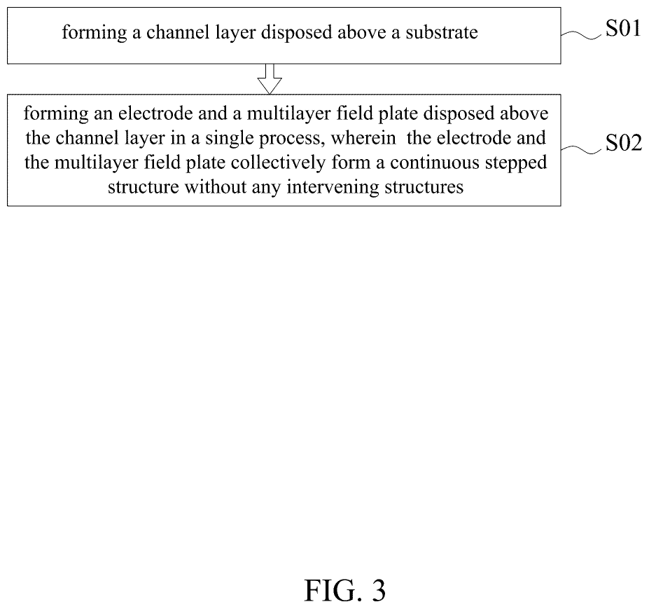

Please refer to FIG. 3, which shows a schematic diagram of the process steps of the semiconductor structure of the present invention. First, in step S01, a channel layer is formed and disposed above a substrate. Next, in step S02, an electrode and a multilayer field plate are formed in a single process and disposed above the channel layer, wherein the multilayer field plate is electrically connected to the electrode, the multilayer field plate includes at least a first field plate and a second field plate, the first field plate partially overlaps and connects with the electrode, and the second field plate partially overlaps and connects with the first field plate, such that the electrode and the multilayer field plate jointly form a continuous stepped structure, wherein the term “partially overlapping and connecting” refers to a configuration of partial direct physical contact and connection without any intervening structure.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A semiconductor structure, comprising:
a substrate,
a channel layer, disposed above the substrate;
an electrode, disposed above the channel layer; and
a multilayer field plate, electrically connected to the electrode, including at least a first field plate and a second field plate,
wherein the first field plate partially overlaps and connects with the electrode, the second field plate partially overlaps and connects with the first field plate, and the electrode and the multilayer field plate are configured to collectively form a continuous stepped structure, and
wherein the term of partially overlapping and connecting refers to a configuration of partially direct physical contact and connection without any intervening structures.

2. The semiconductor structure of claim 1, wherein the electrode is one of a gate electrode, a source electrode, or a drain electrode.

3. The semiconductor structure of claim 1, further comprising a first barrier layer and a first dielectric layer, wherein the first dielectric layer covers the first barrier layer, and the first barrier layer and the first dielectric layer jointly define a contour of the electrode.

4. The semiconductor structure of claim 3, further comprising a second barrier layer and a second dielectric layer, wherein the second dielectric layer covers the second barrier layer, the second barrier layer covers the first dielectric layer, and the second barrier layer and the second dielectric layer jointly define a contour of the first field plate.

5. The semiconductor structure of claim 4, wherein the first barrier layer and the first dielectric layer jointly define a first critical dimension, the second barrier layer and the second dielectric layer jointly define a second critical dimension, and the first critical dimension is smaller than the second critical dimension, and wherein the first critical dimension and the second critical dimension are respectively the maximum lateral dimensions of the electrode and the first field plate.

6. The semiconductor structure of claim 4, wherein the first barrier layer and the second barrier layer are one of an aluminum nitride (AlN) layer, a gallium oxide (Ga₂O₃) layer, or an aluminum oxide (Al₂O₃) layer.

7. The semiconductor structure of claim 4, wherein the first dielectric layer and the second dielectric layer are one of a silicon nitride (SiN) layer, a silicon oxide (SiO₂) layer, a silicon oxynitride (SiON) layer, or a silicon carbide (SiC) layer.

8. The semiconductor structure of claim 1, wherein the substrate is one of a silicon substrate, a sapphire substrate, a silicon carbide substrate, a diamond substrate, or a gallium nitride substrate.

9. A manufacturing method of a semiconductor structure, comprising:
forming a channel layer disposed above a substrate; and
forming an electrode and a multilayer field plate disposed above the channel layer in a single process,
wherein the multilayer field plate is electrically connected to the electrode, the multilayer field plate includes at least a first field plate and a second field plate,
wherein the first field plate partially overlaps and connects with the electrode, the second field plate partially overlaps and connects with the first field plate so that the electrode and the multilayer field plate are configured to collectively form a continuous stepped structure, and
wherein the term of partially overlapping and connecting refers to a configuration of partially direct physical contact and connection without any intervening structures.

10. The manufacturing method of a semiconductor structure of claim 9, wherein the step of forming an electrode and a multilayer field plate comprises:
forming a first barrier layer and a first dielectric layer disposed above the channel layer sequentially;
forming a second barrier layer and a second dielectric layer disposed above the first dielectric layer sequentially;
patterning and etching the second dielectric layer and stopping etching at the second barrier layer to expose a portion of the second barrier layer;
removing the exposed portion of the second barrier layer to expose a portion of the first dielectric layer;
patterning and etching the first dielectric layer and stopping etching at the first barrier layer to expose a portion of the first barrier layer;
removing the exposed portion of the first barrier layer; and
depositing a metal to cover a portion of the channel layer, a portion of the first dielectric layer, and a portion of the second dielectric layer, thereby forming the electrode and the multilayer field plate in the single process,
wherein the first barrier layer and the first dielectric layer jointly define a contour of the electrode, and the second barrier layer and the second dielectric layer jointly define a contour of the first field plate.

11. The manufacturing method of a semiconductor structure of claim 10, wherein the step of patterning and etching the first dielectric layer and the step of removing the exposed portion of the first barrier layer jointly define a first critical dimension, the step of patterning and etching the second dielectric layer and the step of removing the exposed portion of the second barrier layer jointly define a second critical dimension, the first critical dimension is smaller than the second critical dimension, and the first critical dimension and the second critical dimension are respectively the maximum lateral dimensions of the electrode and the first field plate.

12. The manufacturing method of a semiconductor structure of claim 10, wherein the first barrier layer and the second barrier layer are one of an aluminum nitride (AlN) layer, a gallium oxide (Ga₂O₃) layer, or an aluminum oxide (Al₂O₃) layer.

13. The manufacturing method of a semiconductor structure of claim 10, wherein the first dielectric layer and the second dielectric layer are one of a silicon nitride (SiN) layer, a silicon oxide (SiO₂) layer, a silicon oxynitride (SiON) layer, or a silicon carbide (SiC) layer.

14. The manufacturing method of a semiconductor structure of claim 10, wherein etching selectivity ratios of the first dielectric layer and the second dielectric layer relative to the first barrier layer and the second barrier layer are greater than 100.

15. The manufacturing method of a semiconductor structure of claim 9, wherein the substrate is one of a silicon substrate, a sapphire substrate, a silicon carbide substrate, a diamond substrate, or a gallium nitride substrate.
